(19) United States
(12) Patent Application Publication
(10) Pub. No.: US 2025/0221277 A1
(43) Pub. Date: Jul. 3, 2025

(54) DISPLAY DEVICE

(71) Applicant: LG DISPLAY CO., LTD., Seoul (KR)

(72) Inventors: Taehyeon KIM, Paju-si (KR); MyungHo BAN, Paju-si (KR); KyungMin KIM, Paju-si (KR); Sejong SEONG, Paju-si (KR)

(73) Assignee: LG DISPLAY CO., LTD., Seoul (KR)

(21) Appl. No.: 18/913,372

(22) Filed: Oct. 11, 2024

(30) Foreign Application Priority Data
Dec. 29, 2023 (KR) 10-2023-0196483

(51) Int. Cl. H10K 59/80; H10K 59/122; H10K 59/124; H10K 59/38

(52) U.S. Cl. CPC H10K 59/879; H10K 59/122; H10K 59/124; H10K 59/80521; H10K 59/878; H10K 59/38

(57) ABSTRACT

A display device includes a base substrate including a pixel area and a non-pixel area; an overcoat layer disposed on the base substrate, and formed with a groove portion which is recessed in an area corresponding to the non-pixel area; a first electrode formed in an area corresponding to the pixel area, and disposed on the overcoat layer; a light emitting layer disposed on the groove portion and the first electrode; and a second electrode disposed on the light emitting layer, thereby improving light extraction efficiency.

### CROSS-REFERENCE TO RELATED APPLICATION

This application claims the priority of Korean Patent Application No. 10-2023-0196483 filed on Dec. 29, 2023, which is hereby incorporated by reference in its entirety.

### BACKGROUND

### Field of the Disclosure

The present disclosure relates to a display device with improved light extraction efficiency.

### Description of the Background

As the information age has entered, the field of displays which visually express electrical information signals has developed rapidly, and in response to this, various display devices with excellent performance such as thinness, light weight and low power consumption are being developed.

Specific examples of such display devices include a liquid crystal display device (LCD), a plasma display panel device (PDP), a field emission display device (FED), an organic light emitting display device (OLED), and so on.

Among these, the organic light emitting display device does not require a separate light source such as a backlight, and thus, has advantages in that the organic light emitting display device may be manufactured to be light in weight and thin in form and has low power consumption due to low voltage driving.

However, in the organic light emitting display device, a significant portion of light emitted from a light emitting layer is lost while being discharged to the outside by passing through various components, so that light discharged to the outside is only about 20% of light emitted from the light emitting layer.

The amount of light emitted from the light emitting layer increases in proportion to the magnitude of applied current. To improve the luminance of the display device, more current should be provided to the display device. Thus, if light extraction efficiency is not improved, a problem is likely to arise in that power consumption increases.

### SUMMARY

To solve the above-described problem related with light extraction efficiency, by forming a slit in a bank of a display device and then disposing a reflective electrode in the slit, a method of reflecting light of a waveguide mode and extracting the light to the outside has been developed.

The location of the slit in which the reflective electrode is disposed may be determined depending on the height of an overcoat layer which is disposed between the bank and a base substrate. That is to say, the larger the height of the overcoat layer disposed between the bank and the base substrate is, the higher the slit may be located, and the smaller the height of the overcoat layer disposed between the bank and the base substrate is, the lower the slit may be located. Accordingly, when the height of the overcoat layer disposed between the bank and the base substrate is minimized, a second electrode disposed in the slit may be located close to the base substrate to effectively block light of the waveguide mode.

However, there is a disadvantage in that, due to the nature of the overcoat layer made of an organic material, it is difficult to form the overcoat layer disposed between the bank and the base substrate to a desired height. In this case, because the reflective electrode located in the slit is disposed higher than the desired height, a light leakage phenomenon occurs, in which light of the waveguide mode does not reach the reflective electrode and reaches a subpixel disposed adjacently and emitting light of a different color. When the light leakage phenomenon occurs in this way, there is a problem that color mixing between adjacent subpixels is caused, thereby deteriorating the display quality of the display device.

Accordingly, the present disclosure is to provide a display device with improved light extraction efficiency while preventing the light leakage phenomenon, by forming the overcoat layer disposed between the bank and the base substrate to have a minimum height.

Various aspects of the present disclosure may provide a display device with improved light extraction efficiency, by disposing, in a slit of a bank, a second electrode used as a reflective electrode so that light of a waveguide mode totally reflected at an interface between a light emitting layer and an overcoat layer and then traveling sideward is reflected again by the second electrode to be discharged to the outside.

Various aspects of the present disclosure may provide a display device which may be used with low power consumption as light extraction efficiency is improved.

Various aspects of the present disclosure may provide a display device with an improved light leakage phenomenon in which light leaks between a base substrate and a second electrode, by defining a trench of an overcoat layer, in which a bank is seated, up to between a color filter and the base substrate to minimize the height of the overcoat layer disposed between the bank and the base substrate.

Various aspects of the present disclosure may provide a display device with improved aperture ratio and display quality because a light leakage phenomenon is improved without increasing the distance between banks.

Additional features and advantages of the disclosure will be set forth in the description which follows and in part will be apparent from the description, or may be learned by practice of the disclosure. Other advantages of the present disclosure will be realized and attained by the structure particularly pointed out in the written description and claims hereof as well as the appended drawings.

To achieve these and other advantages and in accordance with the present disclosure, as embodied and broadly described, a display device includes a base substrate including a pixel area and a non-pixel area; an overcoat layer disposed on the base substrate, and formed with a groove portion which is recessed in an area corresponding to the non-pixel area; a first electrode formed in an area corresponding to the pixel area, and disposed on the overcoat layer; a light emitting layer disposed on the groove portion and the first electrode; and a second electrode disposed on the light emitting layer.

In another aspect of the present disclosure, a display device includes a pixel area and a non-pixel area surrounding the pixel area defined on a base substrate; an overcoat layer disposed on the base substrate and having a trench portion; a plurality of first electrodes disposed on the overcoat layer and spaced apart from each other, and each first electrode having an end with a lower surface and an upper surface, a bank filled in the trench portion, covering the end of the first electrode, and having a slit disposed in the non-pixel area; a light emitting layer disposed on the first electrode and the bank; and a second electrode disposed in the slit of the bank, wherein the second electrode has a portion located in the slit closer to the based substrate than the first electrode.

According to the aspects of the present disclosure, it is possible to provide a display device with improved light extraction efficiency, by disposing, in a slit of a bank, a second electrode used as a reflective electrode so that light of a waveguide mode totally reflected at an interface between a light emitting layer and an overcoat layer and then traveling sideward is reflected again by the second electrode to be discharged to the outside.

According to the aspects of the present disclosure, it is possible to provide a display device which may be used with low power consumption as light extraction efficiency is improved.

According to the aspects of the present disclosure, it is possible to provide a display device with an improved light leakage phenomenon in which light leaks between a base substrate and a second electrode, by defining a trench of an overcoat layer, in which a bank is seated, up to between a color filter and the base substrate to minimize the height of the overcoat layer disposed between the bank and the base substrate.

According to the aspects of the present disclosure, it is possible to provide a display device with improved aperture ratio and display quality because a light leakage phenomenon is improved without increasing the distance between banks.

It is to be understood that both the foregoing general description and the following detailed description are exemplary and explanatory and are intended to provide further explanation of the disclosure as claimed.

### BRIEF DESCRIPTION OF THE DRAWINGS

The accompanying drawings, which are included to provide a further understanding of the disclosure and are incorporated in and constitute a part of the disclosure, illustrate aspects of the disclosure and together with the description serve to explain the principle of the disclosure.

In the drawings:

FIG. 1 is a system configuration diagram of a display device according to an aspect of the present disclosure;

FIG. 2 is a cross-sectional view of the display device shown in FIG. 1, taken along line A-A′;

FIG. 3 is a view illustrating the paths of light discharged from the display device of FIG. 2;

FIG. 4 is a view illustrating a waveguide mode in a display device;

FIG. 5 is a cross-sectional view of a display device according to another aspect of the present disclosure;

FIG. 6 is a view illustrating a light leakage phenomenon in a display device;

FIG. 7 is a view illustrating a color filter cover according to an aspect of the present disclosure;

FIG. 8 is a view illustrating a color filter cover according to an aspect of the present disclosure;

FIG. 9 is a cross-sectional view taken along line B-B′ of FIG. 1 and illustrates a color filter cover according to an aspect of the present disclosure;

FIG. 10 is of views illustrating a process sequence for manufacturing the color filter cover of FIG. 9;

FIG. 11 is a view illustrating the light paths of a waveguide mode occurring in area “A” of FIG. 2;

FIG. 12 is a view illustrating the light paths of a waveguide mode occurring in area “B” of FIG. 6 and

FIG. 13 is of views illustrating a process sequence for manufacturing the display device according to the aspect of the present disclosure.

### DETAILED DESCRIPTION

In the following description of examples or aspects of the present disclosure, reference will be made to the accompanying drawings in which it is shown by way of illustration specific examples or aspects that may be implemented, and in which the same reference numerals and signs may be used to designate the same or like components even when they are shown in different accompanying drawings from one another. Further, in the following description of examples or aspects of the present disclosure, detailed descriptions of well-known functions and components incorporated herein will be omitted when it is determined that the description may make the subject matter in some aspects of the present disclosure rather unclear. The terms such as “including,” “having,” “containing,” “constituting,” “make up of” and “formed of” used herein are generally intended to allow other components to be added unless the terms are used with the term “only.” As used herein, singular forms are intended to include plural forms unless the context clearly indicates otherwise.

Terms, such as “first,” “second,” “A,” “B,” “(A)” or “(B)” may be used herein to describe elements of the present disclosure. Each of these terms is not used to define essence, order, sequence, number of elements, etc., but is used merely to distinguish the corresponding element from other elements.

When it is mentioned that a first element “is connected or coupled to,” “contacts or overlaps,” etc. a second element, it should be interpreted that, not only may the first element “be directly connected or coupled to” or “directly contact or overlap” the second element, but a third element may also be “interposed” between the first and second elements, or the first and second elements may “be connected or coupled to,” “contact or overlap,” etc. each other via a fourth element. Here, the second element may be included in at least one of two or more elements that “are connected or coupled to,” “contact or overlap,” etc. each other.

When time relative terms, such as “after,” “subsequent to,” “next,” “before” and the like, are used to describe processes or operations of elements or configurations, or flows or steps in operating, processing, manufacturing methods, these terms may be used to describe non-consecutive or non-sequential processes or operations unless the term “directly” or “immediately” is used together.

In addition, when any dimensions, relative sizes, etc. are mentioned, it should be considered that numerical values for elements or features, or corresponding information (e. g., level, range, etc.) include a tolerance or error range that may be caused by various factors (e. g., process factors, internal or external impact, noise, etc.) even when a relevant description is not specified. Further, the term “may” fully encompasses all the meanings of the term “may.”

Hereinafter, various aspects of the present disclosure will be described in detail with reference to accompanying drawings.

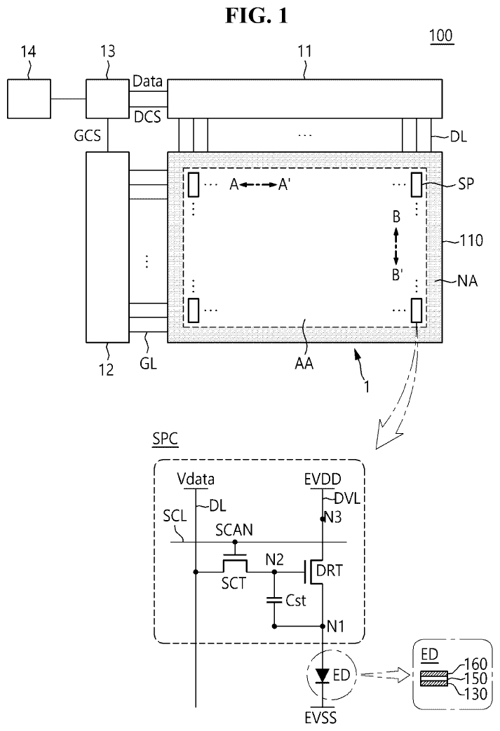

FIG. 1 is a system configuration diagram of a display device according to an aspect of the present disclosure.

Referring to FIG. 1, the display driving system of the display device 100 according to the present disclosure may include a display panel 1 and a display driving circuit for driving the display panel 1.

The display panel 1 may include a display area AA in which an image is displayed and a non-display area NA in which an image is not displayed. The display panel 1 may include a plurality of subpixels SP which are disposed on a base substrate 110 and displays an image.

The display panel 1 may include a plurality of signal wirings which are disposed on the base substrate 110. For example, the plurality of signal wirings may include data lines DL, gate lines GL, and a driving voltage line DVL shown in the pixel driving circuit SPC.

Each of the plurality of data lines DL may be disposed to extend in a first direction (e.g., a column direction or a row direction), and each of the plurality of gate lines GL may be disposed to extend in a direction intersecting the first direction.

The display driving circuit may include a data driving circuit 11 and a gate driving circuit 12, and may further include a controller 13 for controlling the data driving circuit 11 and the gate driving circuit 12.

The data driving circuit 11 may output data signals (also referred to as data voltages) corresponding to an image signal to the plurality of data lines DL. The gate driving circuit 12 may generate gate signals GCS and output the gate signals GCS to the plurality of gate lines GL. The controller 13 may convert input image data Data inputted from an external host 14 to suit a data signal DCS format employed in the data driving circuit 11, and may supply the converted image data to the data driving circuit 11.

The data driving circuit 11 may include at least one source driver integrated circuit. For example, each source driver integrated circuit may be connected to the display panel 1 in a tape automated bonding (TAB) method, may be connected to the bonding pads of the display panel 1 in a chip-on-glass (COG) or chip-on-panel (COP) method, or may be connected to the display panel 1 by being implemented in a chip-on-film (COF) method.

The gate driving circuit 12 may be connected to the display panel 1 in a tape automated bonding (TAB) method, may be connected to the bonding pads of the display panel 1 in a COG or COP method, may be connected to the display panel 1 according to a COF method, or may be formed in the non-display area NA of the display panel 1 in a gate-in-panel (GIP) type.

Referring back to FIG. 1, in the display device 100 according to the present disclosure, each subpixel SP may include a light emitting element ED and a pixel driving circuit SPC for driving the light emitting element ED. The pixel driving circuit SPC may include a driving transistor DRT, a scan transistor SCT and a storage capacitor Cst.

The driving transistor DRT may drive the light emitting element ED by controlling current flowing to the light emitting element ED. The scan transistor SCT may transfer a data voltage Vdata to a second node N2, which is the gate node of the driving transistor DRT. The storage capacitor Cst may be configured to maintain a voltage for a predetermined period of time.

The light emitting element ED may include a first electrode 130, a second electrode 160, and a light emitting layer 150 located between the first electrode 130 and the second electrode 160. The first electrode 130 may be a pixel electrode which is involved in the formation of the light emitting element ED of each subpixel SP, and may be electrically connected to a first node N1 of the driving transistor DRT. The second electrode 160 may be a common electrode which is involved in the formation of light emitting elements ED of all subpixels SP, and may be applied with a base voltage EVSS.

For example, the light emitting element ED may be an organic light emitting diode (OLED), an inorganic-based light emitting diode (LED) or a quantum dot light emitting element which is a semiconductor crystal that emits light on its own.

The driving transistor DRT as a transistor for driving the light emitting element ED may include the first node N1, the second node N2 and a third node N3. The first node N1 may be a source or drain node, and may be electrically connected to the first electrode 130 of the light emitting element ED. The second node N2 may be the gate node, and may be electrically connected to a source or drain node of the scan transistor SCT. The third node N3 may be a drain or source node, and may be electrically connected to the driving voltage line DVL which supplies a driving voltage EVDD. Hereinbelow, for the sake of convenience in explanation, it may be described as an example that the first node N1 is a source node and the third node N3 is a drain node.

The scan transistor SCT may switch the connection between a data line DL and the second node N2 of the driving transistor DRT. In response to a scan signal SCAN supplied from a scan line SCL as a type of gate line GL, the scan transistor SCT may control the connection between the second node N2 of the driving transistor DRT and a corresponding data line DL among the plurality of data lines DL.

The storage capacitor Cst may be configured between the first node N1 and the second node N2 of the driving transistor DRT.

The structure of the subpixel SP illustrated in FIG. 1 is nothing but a mere example for explanation, and may further include at least one transistor or at least one capacitor. Each of the plurality of subpixels SP may have the same structure, or some of the plurality of subpixels SP may have a different structure. Each of the driving transistor DRT and the scan transistor SCT may be an n-type transistor or a p-type transistor.

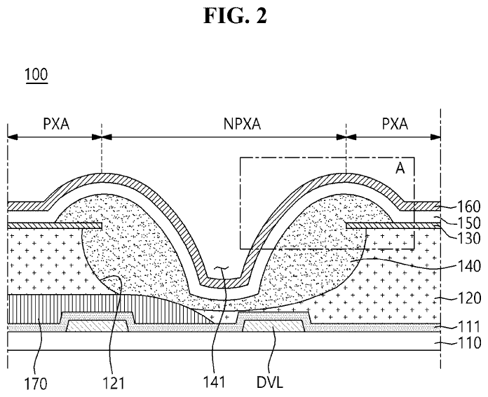

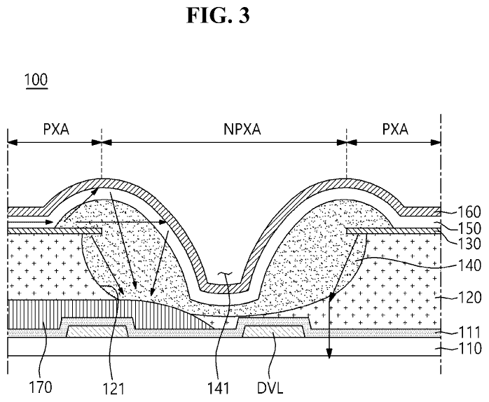

FIG. 2 is a cross-sectional view of the display device shown in FIG. 1, taken along line A-A′, and FIG. 3 is a view illustrating the paths of light discharged from the display device of FIG. 2.

Referring to FIGS. 2 and 3, the display device 100 may include the base substrate 110, an overcoat layer 120, the first electrode 130, a bank 140, the light emitting layer 150, and the second electrode 160.

The base substrate 110 is to support various components of the display device 100, and may be formed of an insulating material such as a glass substrate or a plastic substrate.

The base substrate 110 may include a pixel area PXA where circuit elements constituting the subpixel SP and the light emitting element ED are formed, and a non-pixel area NPXA which surrounds the pixel area PXA around the pixel area PXA. In the present aspect, the pixel area PXA may be defined as an area where the first electrode 130 is disposed, and the non-pixel area NPXA may include the boundary between adjacent subpixels SP and/or the non-display area NA.

A thin film transistor and metal wirings may be located on the base substrate 110. For example, a metal wiring may be the driving voltage line DVL. To protect the thin film transistor and the metal wirings, a passivation layer 111 may be further disposed on the base substrate 110.

The overcoat layer 120 as a planarization layer for alleviating a step of an underlying structure may be disposed on the base substrate 110. For example, the overcoat layer 120 may be made of an organic material such as polyimide, benzocyclobutene series resin or acrylate.

A trench portion 121 may be formed in the upper portion of the overcoat layer 120 as the non-pixel area NPXA and a portion of the pixel area PXA around the non-pixel area NPXA are recessed. For example, the width of the trench portion 121 formed in the overcoat layer 120 may be larger than that of the non-pixel area NPXA, and the trench portion 121 may be formed to be convex outward.

The first electrode 130 as an anode may be independently disposed in each subpixel SP. For example, the first electrode 130 may be formed as a transparent electrode such as indium tin oxide (ITO) and indium zinc oxide (IZO), or may be formed as an opaque electrode such as aluminum (Al), copper (Cu) and nickel (Ni). Besides, the first electrode 130 may be formed as a transparent electrode and an opaque electrode are stacked.

The first electrode 130 may be provided in a plural number and be disposed on the overcoat layer 120 to be spaced apart from each other, and each end of the first electrode 130 may overlap the trench portion 121. In other words, the trench portion 121 is formed to have a larger width than the non-pixel area NPXA, and the edge of the trench portion 121 is located under the first electrode 130 so that the end of the first electrode 130 overlaps the trench portion 121.

The length of the first electrode 130 which overlaps the trench portion 121 may be at least 0.5 times the wavelength of the light emitting layer 150 to reduce light spread due to diffraction. For example, when the wavelength of the light emitting layer 150 is 380 nm to 780 nm, the length of the first electrode 130 which overlaps the trench portion 121 may be 190 nm to 390 nm or more.

The bank 140 is to partition pixels, and may be disposed on the overcoat layer 120. For example, the bank 140 may be disposed in and around the trench portion 121 to cover the side portion of the first electrode 130, and may be formed with a slit 141 on the upper surface thereof. Specifically, when viewed on the basis of the first electrode 130, the lower portion of the bank 140 may be disposed in the trench portion 121, and the upper portion of the bank 140 may be formed to be larger than the width of the trench portion 121 to cover the side portion of the first electrode 130. Accordingly, the end of the first electrode 130 may be disposed in the bank 140.

The light emitting layer 150 may be disposed on the first electrode 130 and the bank 140. Namely, the light emitting layer 150 may be disposed in the pixel area PXA and the non-pixel area NPXA, and may be disposed in the slit 141 of the bank 140 in the non-pixel area NPXA.

For example, the light emitting layer 150 may be an organic light emitting layer including a hole injection layer (HIL), a hole transport layer (HTL), an emission material layer (EML), an electron transport layer (ETL) and an electron injection layer (EIL) as organic compound layers.

The second electrode 160 as a cathode may be disposed on the light emitting layer 150. For example, the second electrode 160 may be provided in the pixel area PXA and the non-pixel area NPXA, and may be disposed in the slit 141 of the bank 140 in the non-pixel area NPXA.

The second electrode 160 in the present disclosure may be used as a reflective electrode. To this end, the second electrode 160 may be made of an opaque electrode such as aluminum (Al), copper (Cu) and nickel (Ni) having good reflectivity. Besides, the second electrode 160 may be formed as a structure in which a transparent electrode such as indium tin oxide (ITO) and indium zinc oxide (IZO) and an opaque electrode are stacked.

In this way, as the second electrode 160 used as a reflective electrode is disposed in the slit 141 of the bank 140, light of a waveguide mode can be extracted to the outside and improves luminance.

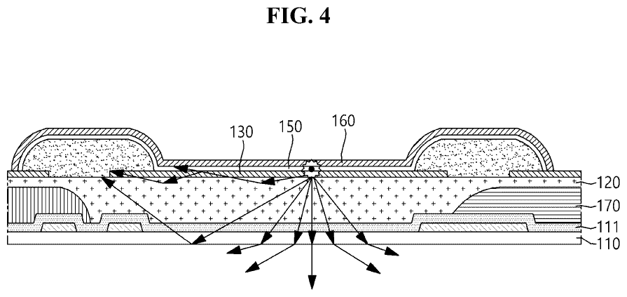

FIG. 4 is a view illustrating a waveguide mode in a display device. The waveguide mode will be described with reference to FIG. 4 as follows.

Referring to FIG. 4, in light generated from the light emitting layer 150, there is light that is not emitted to the outside due to a difference in refractive index between the light emitting layer 150 and the overcoat layer 120 in contact with the light emitting layer 150 and is totally reflected. Light totally reflected in this way is not emitted to the outside and is trapped inside. This light is referred to as light of a waveguide mode. The light of the waveguide mode is totally reflected at the interface between the light emitting layer 150 and the overcoat layer 120 and then travels sideward to disappear, which is a cause for a decrease in light extraction efficiency.

To solve the problem of the waveguide mode, in the display device 100 according to the aspect of the present disclosure, the second electrode 160 may be disposed in the slit 141 of the bank 140. That is to say, as shown in FIG. 3, by disposing the second electrode 160, located in the slit 141, at a lower location than the first electrode 130, even when light travels sideward by the waveguide mode, the light may be reflected again by the second electrode 160 located in the slit 141 to be discharged to the outside.

Accordingly, light extraction efficiency may be improved, and due to the improvement in light extraction efficiency, it is possible to provide the display device 100 capable of being used with low power consumption.

According to the present aspect, the slit 141 formed in the bank 140 may be formed between the first electrodes 130, and both sides of the slit 141 may be formed to narrow in width in a downward direction. Both sides of the slit 141 may be formed to have a slope of about 30 to 70°. Due to the slope of the slit 141, the light emitting layer 150 and the second electrode 160 located in the slit 141 may also be formed to have a slope of 30 to 70°. Accordingly, light of the waveguide mode traveling sideward may be totally reflected downward by the sloped surface of the second electrode 160.

Both sides of the slit 141 may be formed to be convex inward. When both sides of the slit 141 are formed to be convex in this way, the lengths of the light emitting layer 150 and the second electrode 160 disposed in the slit 141 may increase to improve luminous efficiency. In addition, since light may be provided through various paths compared to a straight light emitting layer 150, left and right viewing angles may be improved.

The display device 100 according to the present aspect may further include a color filter 170.

The color filter 170 may be provided in a plural number to be disposed between the base substrate 110 and the overcoat layer 120, and may each overlap the pixel area PXA and the non-pixel area NPXA. The plurality of color filters 170 may be formed to correspond to the colors of subpixels SP corresponding thereto. For example, when subpixels SP are composed of a red subpixel, a green subpixel and a blue subpixel, the color filters 170 may be composed of a red color filter, a green color filter and a blue color filter to correspond thereto. When a subpixel SP is composed of a white subpixel, a color filter 170 may not be provided.

The color filter 170 may be exposed to the outside of the overcoat layer 120 in the non-pixel area NPXA due to the presence of the trench portion 121. The color filter 170 may be formed to include dye, pigment, dispersing agent, etc., which are small molecules and thus serve as a cause for outgassing in the course of degradation. Therefore, when the color filter 170 is exposed to the outside of the overcoat layer 120, out-gas may move toward the subpixel to cause pixel shrinkage.

To prevent such pixel shrinkage, the color filter 170 which is exposed to the trench portion 121 may be covered through the bank 140. In other words, as shown in FIG. 2, by forming the slit 141 defined in the bank 140 into a groove shape with a residual layer in the non-pixel area NPXA, the exposed portion of the color filter 170 may be shielded.

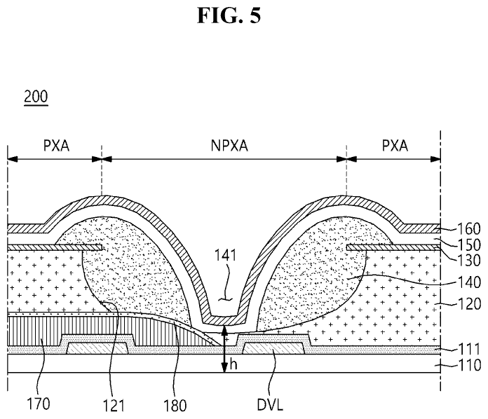

FIG. 5 is a cross-sectional view of a display device according to another aspect of the present disclosure. In the present aspect, description will be made mainly on differences from the aspect described above.

Referring to FIG. 5, the slit 141 of a display device 200 may be formed into a hole shape with no residual layer of the bank 140 in the non-pixel area NPXA. Namely, the slit 141 in the aspect shown in FIG. 2 is formed into a groove shape with a residual layer in the non-pixel area NPXA, but in the present aspect, the slit 141 is formed into a hole shape with no residual layer.

In this way, as the slit 141 is formed into a hole shape, the bank 140 may be divided with the slit 141 interposed between portions of the bank 140. Accordingly, since the second electrode 160 located in the slit 141 may be located closer to the base substrate 110, a light leakage phenomenon can be effectively prevented.

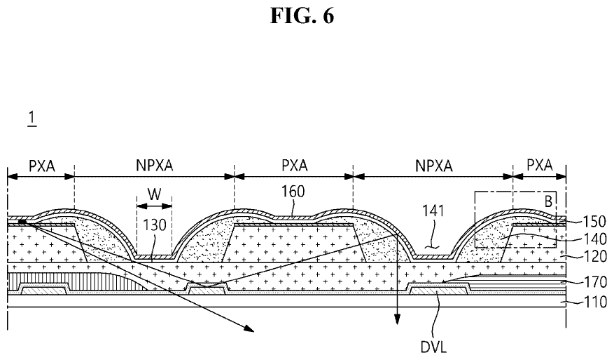

FIG. 6 is a view illustrating a light leakage phenomenon in a display device. The light leakage phenomenon will be described with reference to FIG. 6 as follows.

The second electrode 160 located in the slit 141 of the bank 140 may be located higher or lower depending on the distance between the base substrate 110 and the slit 141. If, as shown in FIG. 6, the distance between the base substrate 110 and the slit 141 is formed larger than a preset value, a portion of light totally reflected at the interface between the light emitting layer 150 and the overcoat layer 120 may not reach the second electrode 160 but may reach an adjacently disposed subpixel SP which emits light of a different color. This is called a light leakage phenomenon, and the light leakage phenomenon causes color mixing between adjacent subpixels SP, resulting in deterioration in display quality. To solve the problem of light leakage, a gap W between banks 140 may be widened, but in this case, the area of the non-pixel area NPXA may increase and thus the aperture ratio of a display device 1 may decrease.

Therefore, to solve the problem of light leakage without decreasing aperture ratio, in the display device 100 according to the aspect, a height h between the base substrate 110 and the bank 140 may be minimized.

Specifically, as shown in FIG. 5, the trench portion 121 formed in the overcoat layer 120 may be recessed up to between the color filter 170 and the base substrate 110 to expose a portion of the color filter 170 to the outside. After forming the hole-shaped slit 141 in the bank 140 disposed in the trench portion 121, by disposing the second electrode 160 in the slit 141, the distance between the base substrate 110 and the second electrode 160 may be minimized to prevent the light leakage phenomenon. Accordingly, since it is possible to prevent the light leakage phenomenon even without increasing the gap W between banks 140, aperture ratio and display quality may be improved.

In the case where the slit 141 of the bank 140 is formed into a hole shape with no residual layer in the non-pixel area NPXA, the color filter 170 may be exposed to the outside of the overcoat layer 120 by the trench portion 121. In this way, when the color filter 170 is exposed to the outside of the overcoat layer 120, pixel shrinkage may occur, and thus, a color filter cover 180 may be provided to cover the upper portion of the color filter 170.

The color filter cover 180 may be made of an inorganic layer including an Si-based material to cover the color filter 170. That is to say, because the Si-based inorganic layer has good light transparency and is not etched while performing dry etching for forming the trench portion 121 of the overcoat layer 120, the Si-based inorganic layer may protect the color filter 170. Accordingly, it is possible to prevent pixel shrinkage due to exposure of the color filter 170.

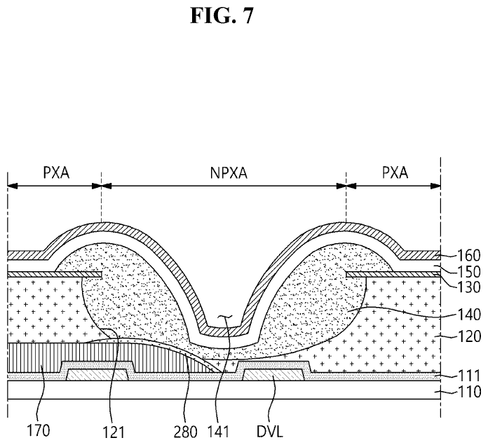

FIG. 7 is a view illustrating a color filter cover according to an aspect of the present disclosure. In the present aspect, description will be made mainly on differences from the aspects described above.

Referring to FIG. 7, a color filter cover 280 may cover only a portion of the color filter 170 which is exposed by the trench portion 121. In other words, the color filter cover 280 may be formed to cover only a portion of the color filter 170 which is likely to be affected when performing etching of the overcoat layer 120 to form the trench portion 121. Accordingly, by preventing light loss caused as the color filter cover 280 is disposed in the pixel area PXA, it is possible to improve light transmittance.

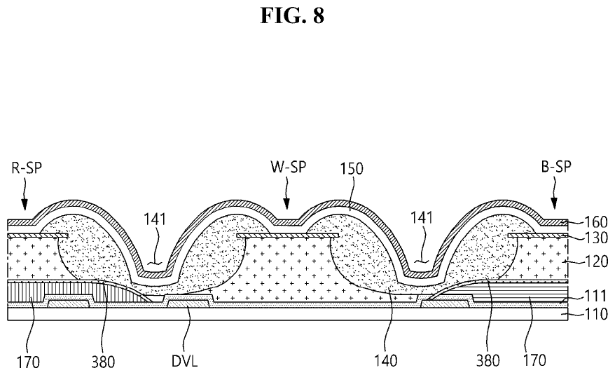

FIG. 8 is a view illustrating a color filter cover according to an aspect of the present disclosure. In the present aspect, description will be made mainly on differences from the aspects described above.

Referring to FIG. 8, a color filter cover 380 may be provided only to a color filter 170 which is adjacent to a white subpixel W-SP. For example, when subpixels SP are composed of a red subpixel R-SP, a white subpixel W-SP, a green subpixel G-SP and a blue subpixel B-SP, color filter covers 380 may be provided only to the color filters 170 of the red subpixel R-SP and the blue subpixel B-SP which are adjacent to the white subpixel W-SP. This is because mixing red, green and blue does not have a significant effect on color perception and color coordinates but mixing white with red, green and blue causes a discoloration defect. Therefore, when the color filter covers 380 are disposed only on the color filters 170 which are adjacent to the white subpixel W-SP, color mixing may be prevented and at the same time light transmittance may be improved.

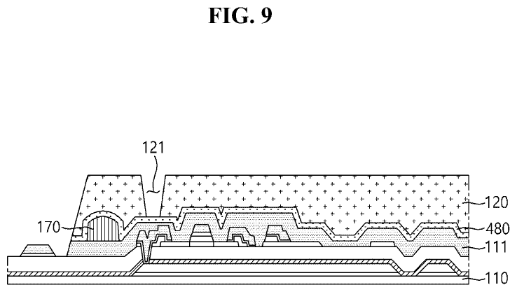

FIG. 9 is a view illustrating a color filter cover according to an aspect of the present disclosure. FIG. 9 is a cross-sectional view taken along line B-B′ of FIG. 1.

Referring to FIG. 9, a color filter cover 480 may be formed to cover the color filter 170 and the passivation layer 111. In this way, when the color filter cover 480 is formed to cover both the color filter 170 and the passivation layer 111, the color filter cover 480 may be manufactured by reusing a mask used to deposit the passivation layer 111. Therefore, since there is no need to add a mask to manufacture the color filter cover 480, the manufacturing cost may be reduced.

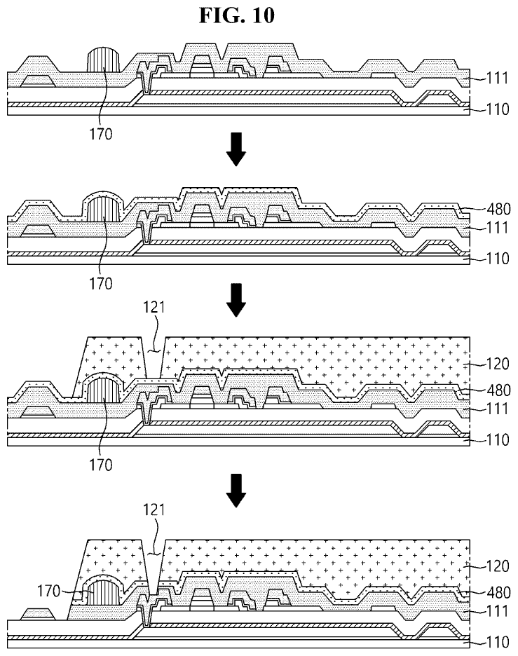

FIG. 10 is of views illustrating a process sequence for manufacturing the color filter cover of FIG. 9. A procedure for manufacturing the color filter cover 480 will be schematically described with reference to FIG. 10 as follows.

Referring to FIG. 10, first, the passivation layer 111 is formed on the base substrate 110 using a passivation mask. After forming the color filter 170 on the passivation layer 111, by reusing the passivation mask, the color filter cover 480 may be deposited on the color filter 170 and the passivation layer 111.

When the color filter cover 480 is manufactured in this way, the overcoat layer 120 which has the trench portion 121 may be formed on the color filter cover portion 480 using an overcoat layer mask. By performing etching through an etching process so that the bottom surface of the trench portion 121 is located between the overcoat layer 120 and the color filter 170, the color filter cover 480 may be obtained.

According to the present aspect, the refractive index of the bank 140 may be determined to be greater than the refractive index of the first electrode 130. For example, when the refractive index of the bank 140 is 1.9 to 2.0, the refractive index of the first electrode 130 may be determined to be 1.6 to 1.8. In this way, when the refractive index of the bank 140 is determined to be greater than the refractive index of the first electrode 130, light generated from the light emitting layer 150 may be refracted downward when passing between the bank 140 and the first electrode 130 and be discharged to the outside. Namely, in consideration of the nature of light traveling from a location with a greater refractive index to a location with a smaller refractive index, when the refractive index of the bank 140 is determined to be greater than the refractive index of the first electrode 130, since light generated from the light emitting layer 150 is discharged while being refracted downward at the interface between the first electrode 130 and the bank 140, light extraction efficiency may be improved.

The refractive index of the bank 140 may be determined to be greater than the refractive index of the overcoat layer 120. Accordingly, light generated from the light emitting layer 150 may be discharged while being refracted, in a direction where the bank 140 is located, at the interface between the overcoat layer 120 located under the first electrode 130 and the bank 140. Accordingly, light loss due to light of the waveguide mode traveling sideward may be reduced, and light extraction efficiency may be improved.

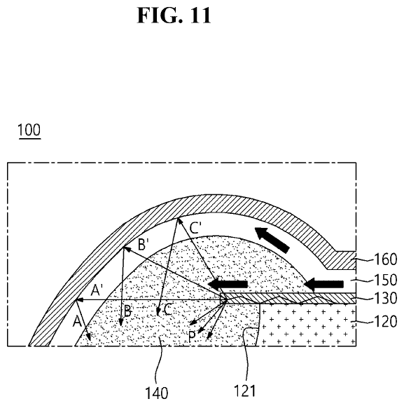

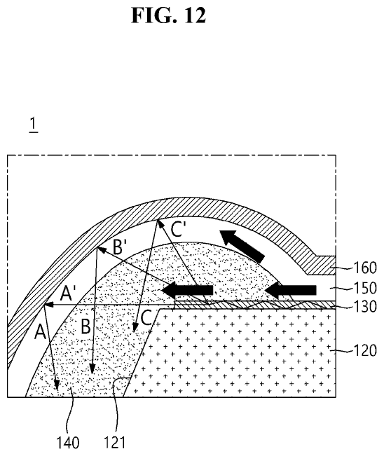

FIG. 11 is a view illustrating the light paths of a waveguide mode occurring in area “A” of FIG. 2, and FIG. 12 is a view illustrating the light paths of a waveguide mode occurring in area “B” of FIG. 6.

Referring to FIGS. 11 and 12, the display device 100 according to the present aspect has differences in that the trench portion 121 defined in the overcoat layer 120 is formed to be convex outward and the end of the first electrode 130 is formed to protrude out of the overcoat layer 120 and overlap the trench portion 121. Due to these differences, in the display device 100 according to the present aspect, since light of P paths is additionally generated in the waveguide mode, light extraction efficiency may be improved.

Specifically, in the display device 1 shown in FIG. 12, light of the waveguide mode traveling sideward at the interface between the light emitting layer 150 and the overcoat layer 120 may be reflected by the second electrode 160 to be discharged through paths A, B and C. Therefore, although light of the waveguide mode may be extracted to the outside, light is absorbed as much as paths A′, B′ and C′, and thus, light extraction efficiency may be somewhat reduced.

On the other hand, in the display device 100 according to the present aspect, by defining an undercut structure under the first electrode 130, the end of the first electrode 130 is formed to overlap the trench portion 121. Therefore, since the P paths are additionally generated in the waveguide mode, a decrease in light efficiency caused due to the aforementioned paths A′, B′ and C′ may be compensated for.

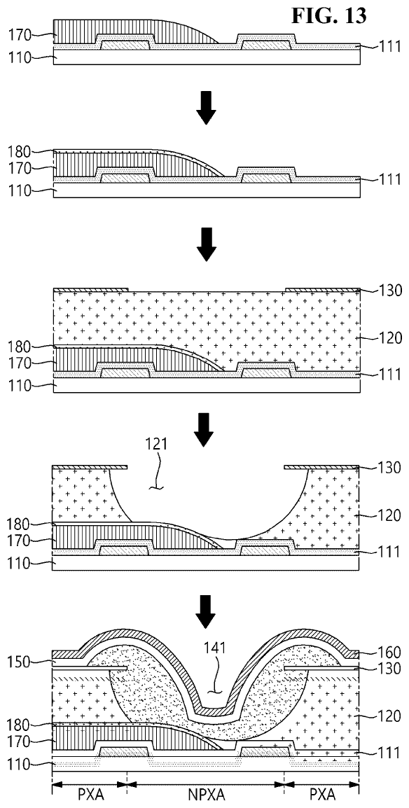

FIG. 13 is of views illustrating a process sequence for manufacturing the display device according to the aspect of the present disclosure. A procedure for manufacturing a display device will be schematically described with reference to FIG. 13 as follows.

First, after patterning the color filter 170 on the base substrate 110, the color filter cover 180 may be deposited on the color filter 170 using an Si-based material.

After forming the overcoat layer 120 and the first electrode 130, a photolithography process and an etching process may be performed on the overcoat layer 120 disposed between first electrodes 130 using a photo mask. Accordingly, the trench portion 121 may be formed in the overcoat layer 120 to overlap the end of the first electrode 130. That is to say, the trench portion 121 may be formed in a portion of the pixel area PXA and the non-pixel area NPXA to overlap the end of the first electrode 130.

Thereafter, the bank 140 with the slit 141 in the non-pixel area NPXA may be formed using a photo mask. When sequentially stacking the light emitting layer 150 and the second electrode 160 in the pixel area PXA and the non-pixel area NPXA, it is possible to manufacture the display device 100 with the slit 141 of a tapered structure in the non-pixel area NPXA. Although not shown, the display device 100 may be further provided with an encapsulation layer for planarizing the top of the second electrode 160 and blocking moisture from being introduced from the outside.

Brief description of the aspects of the present disclosure described above is as follows.

According to aspects of the present disclosure, a display device may include a base substrate including a pixel area and a non-pixel area surrounding the pixel area; an overcoat layer disposed on the base substrate, and formed with a trench portion as the non-pixel area and a portion of the pixel area around the non-pixel area are recessed; a first electrode provided in a plural number to be disposed on the overcoat layer and be spaced apart, and having an end which overlaps the trench portion; a bank disposed in and around the trench portion to cover a side portion of the first electrode, and formed with a slit on an upper surface thereof; a light emitting layer disposed on the first electrode and the bank; and a second electrode disposed on the light emitting layer.

According to the aspects of the present disclosure, a refractive index of the bank may be determined to be greater than a refractive index of the first electrode.

According to the aspects of the present disclosure, a refractive index of the bank may be determined to be greater than a refractive index of the overcoat layer.

According to the aspects of the present disclosure, the second electrode located in the slit may be disposed at a lower location than the first electrode.

According to the aspects of the present disclosure, light traveling to a side of the light emitting layer may be reflected by the second electrode located in the slit to be discharged to an outside.

According to the aspects of the present disclosure, the slit may be formed between first electrodes.

According to the aspects of the present disclosure, both sides of the slit may be formed so that a width between the sides gradually decreases in a downward direction.

According to the aspects of the present disclosure, both sides of the slit may be formed to be convex inward.

According to the aspects of the present disclosure, the slit may be formed in a groove shape with a residual layer of the bank in the non-pixel area.

According to the aspects of the present disclosure, the slit may be formed in a hole shape with no residual layer of the bank in the non-pixel area.

According to the aspects of the present disclosure, a length of the first electrode overlapping the trench portion may be determined to be at least 0.5 times a wavelength of the light emitting layer.

According to the aspects of the present disclosure, the trench portion may be formed to be convex outward.

According to the aspects of the present disclosure, the display device may further include a color filter disposed between the base substrate and the overcoat layer, and overlapping the pixel area and the non-pixel area.

According to the aspects of the present disclosure, the trench portion defined in the overcoat layer may be formed to be recessed up to between the color filter and the base substrate to expose a portion of the color filter to an outside.

According to the aspects of the present disclosure, the color filter exposed to the trench portion may be shielded by the bank.

According to the aspects of the present disclosure, the display device may further include a color filter cover covering an upper surface of the color filter.

According to the aspects of the present disclosure, the color filter cover may include an Si-based material.

According to the aspects of the present disclosure, the color filter cover may cover only a portion of the color filter which is exposed to the trench portion.

According to the aspects of the present disclosure, the color filter cover may be provided only to a color filter which is adjacent to a white subpixel.

According to the aspects of the present disclosure, the display device may further include a passivation layer disposed between the base substrate and the color filter, and the color filter cover may cover the color filter and the passivation layer.

According to the aspects of the present disclosure, a display device may include a pixel area and a non-pixel area surrounding the pixel area defined on a base substrate; an overcoat layer disposed on the base substrate and having a trench portion; a plurality of first electrodes disposed on the overcoat layer and spaced apart from each other, and each first electrode having an end with a lower surface and an upper surface, a bank filled in the trench portion, covering the end of the first electrode, and having a slit disposed in the non-pixel area; a light emitting layer disposed on the first electrode and the bank; and a second electrode disposed in the slit of the bank, wherein the second electrode has a portion located in the slit closer to the based substrate than the first electrode.

According to the aspects of the present disclosure, the upper surface is covered with the bank more than the lower surface.

The above description has been presented to enable any person skilled in the art to make and use the technical idea of the present disclosure, and has been provided in the context of a particular application and its requirements. Various modifications, additions and substitutions to the described aspects will be readily apparent to those skilled in the art, and the general principles defined herein may be applied to other aspects and applications without departing from the spirit and scope of the present disclosure. The above description and the accompanying drawings provide an example of the technical idea of the present disclosure for illustrative purposes only. Thus, it is intended that the present disclosure covers the modifications and variations of the aspects provided they come within the scope of the appended claims and their equivalents.

What is claimed is:

1. A display device comprising:
a base substrate including a pixel area and a non-pixel area surrounding the pixel area;
an overcoat layer disposed on the base substrate and formed with a trench portion in the non-pixel area and a portion of the pixel area around the non-pixel area are recessed;
a plurality of first electrodes disposed on the overcoat layer and spaced apart from each other, and each having an end which overlaps the trench portion;
a bank disposed in and around the trench portion and covering a side portion of the first electrode, and formed with a slit on an upper surface thereof;
a light emitting layer disposed on the first electrode and the bank; and
a second electrode disposed on the light emitting layer.

2. The display device of claim 1, wherein the bank has a refractive index greater than a refractive index of the first electrode.

3. The display device of claim 1, wherein the bank has a refractive index greater than a refractive index of the overcoat layer.

4. The display device of claim 1, wherein the second electrode has a portion located in the slit disposed at a vertical location lower than the first electrode.

5. The display device of claim 1, wherein the second electrode located in the slit reflects light traveling to a side of the light emitting layer to discharge to outside.

6. The display device of claim 1, wherein the slit is formed between the plurality of first electrodes.

7. The display device of claim 1, wherein both sides of the slit are formed to have a width between the both sides that gradually decreases in a downward direction.

8. The display device of claim 1, wherein both sides of the slit are formed to be convex inward.

9. The display device of claim 1, wherein the slit is formed in a groove shape with a residual layer of the bank in the non-pixel area.

10. The display device of claim 1, wherein the slit is formed in a hole shape with no residual layer of the bank in the non-pixel area.

11. The display device of claim 1, wherein the first electrode has a length overlapping the trench portion at least 0.5 times of a wavelength of the light emitting layer.

12. The display device of claim 1, wherein the trench portion is formed to be convex outward.

13. The display device of claim 1, further comprising a color filter disposed between the base substrate and the overcoat layer, and overlapping the pixel area and the non-pixel area.

14. The display device of claim 13, wherein the trench portion defined in the overcoat layer is formed to be recessed up to between the color filter and the base substrate to expose a portion of the color filter to outside.

15. The display device of claim 14, wherein the color filter has a portion exposed to the trench portion that is shielded by the bank.

16. The display device of claim 13, further comprising a color filter cover covering an upper surface of the color filter.

17. The display device of claim 16, wherein the color filter cover includes a Si-based material.

18. The display device of claim 16, wherein the color filter cover covers only a portion of the color filter which is exposed to the trench portion.

19. The display device of claim 16, wherein the color filter cover is provided only on the color filter which is adjacent to a white subpixel.

20. The display device of claim 16, further comprising a passivation layer disposed between the base substrate and the color filter,
wherein the color filter cover covers the color filter and the passivation layer.

21. A display device comprising:
a pixel area and a non-pixel area surrounding the pixel area defined on a base substrate;
an overcoat layer disposed on the base substrate and having a trench portion;
a plurality of first electrodes disposed on the overcoat layer and spaced apart from each other, and each first electrode having an end with a lower surface and an upper surface,
a bank filled in the trench portion, covering the end of the first electrode, and having a slit disposed in the non-pixel area;
a light emitting layer disposed on the first electrode and the bank; and
a second electrode disposed in the slit of the bank,
wherein the second electrode has a portion located in the slit closer to the based substrate than the first electrode.

22. The display device of claim 21, wherein the upper surface is covered with the bank more than the lower surface.
